(19) United States
(12) Patent Application Publication
(10) Pub. No.: US 2003/0049948 A1
(43) Pub. Date: Mar. 13, 2003

(54) Apparatus and method for coupling buses

(76) Inventors: David J. Kim, San Jose, CA (US); Dimitry Struve, Los Altos, CA (US); William W. Ruckman, San Jose, CA (US); Anthony Kozaczuk, Burlingame, CA (US)

Correspondence Address: WILLIAMS, MORGAN & AMERSON, P.C., 10333 RICHMOND, SUITE 1100, HOUSTON, TX, 77042, US

(21) Appl. No.: 09/951,999

(22) Filed: Sep. 13, 2001

(51) Int. Cl. H01R 12/00; H05K 1/00

(52) U.S. Cl. 439/61

(57) ABSTRACT

A computer assembly includes a motherboard having a first bus extending to a first connector and a riser card having a second bus extending to a plurality of connectors and extending to a second connector adapted to mate with the first contact set of the motherboard to couple the first bus with the second bus. The computer assembly further includes a first expansion card having a third bus extending to a third connector adapted to mate with one of the plurality of connectors of the riser card to couple the third bus with the second bus. A method includes driving a first signal onto a motherboard bus, transmitting the first signal over the motherboard bus to a riser card bus, and transmitting the first signal over the riser card bus to a plurality of expansion card buses.

### BACKGROUND OF THE INVENTION

1. Field of the Invention

This invention relates to a method and apparatus for coupling buses in a computer system.

2. Description of the Related Art

Computer systems are general-purpose devices that may be modified to perform particular tasks or functions. Generally, computer systems include a motherboard, a power source, and other components mounted within an enclosure. The motherboard typically includes a number of connectors or slots in which special purpose printed circuit boards or “cards”, e.g., peripheral component interface (PCI) bus cards, industry standard architecture (ISA) bus cards, proprietary bus cards, and the like, may be inserted. These special purpose cards may be used to add to or enhance the functionality of the computer system. For example, a conventional computer system may have its graphics capability enhanced by the addition of a graphics card. Similarly, the sound-producing capability of the computer system may be enhanced by the addition of a sound card.

One limitation on the ability to add or enhance the functionality of the computer system is the size constraints of the computer system enclosure. In particular, height constraints placed on the computer system enclosure can dictate whether any cards can be directly attached to the motherboard and, if so, the physical dimensions of the card. For example, if the height of the card is greater than the height of the computer system enclosure, there will not be enough room to physically fit the card within the enclosure, as in a “1U” height enclosure. A “1U” height enclosure, as defined by the International Electromechanical Commission, is an enclosure having a height of 44.45 mm. In cases like this, it can be desirable to locate the cards parallel to the motherboard, as illustrated in FIG. 1. Conventional motherboards, such as a motherboard 102, have connectors 118, 120 that are mounted on a surface 106 of the motherboard. A riser card 108 having contacts (not shown) along its edge 110 and a connector 112 may be inserted into the connector 104 so that a card 114 can be located parallel to the motherboard 102. Electrical signals are transmitted to the card 114 from the connector 112 through contacts (not shown) along the edge of the card 114.

While minimizing the effects of the height restriction, locating the card 114 parallel to the motherboard 102 can create problems. For example, the card 114 may cover other connectors 118, 120 and therefore prevent cards (not shown) from being connected to the connectors 118, 120. Further, only one card (e.g., the card 114) may be located parallel to the motherboard 102.

Referring to FIG. 2, enclosures that have greater heights, such as “2U” enclosures, may have heights that are great enough so that cards 202, 204, 206 may be inserted directly into connectors 208, 210, 212. In this case, the cards 202, 204, 206 may be located perpendicular to a motherboard 216; however, the motherboard 216 may have only a few connectors 208, 210, 212 due to limited available area on the surface 214 of the motherboard 216. Further, “2U” enclosures have heights that are only sufficient for low profile cards, which may have limited availability.

Thus, there is a need for improved apparatuses and methods to enable the placement and connection of cards parallel to the motherboard within a computer system enclosure.

### SUMMARY OF THE INVENTION

In one aspect of the present invention a computer assembly is presented including a motherboard having a first bus extending to a first connector and a riser card having a second bus extending to a plurality of connectors and extending to a second connector adapted to mate with the first contact set of the motherboard to couple the first bus with the second bus. The computer assembly further includes a first expansion card having a third bus extending to a third connector adapted to mate with one of the plurality of connectors of the riser card to couple the third bus with the second bus.

In another aspect of the present invention, a riser card is presented including a primary connector, a plurality of secondary connectors, and a printed circuit card having a bus extending to the primary connector and to the plurality of secondary connectors. The primary connector is adapted to mate with a connector of a motherboard to couple the bus of the printed circuit card with a bus of a motherboard and each of the plurality of secondary connectors is adapted to mate with a connector of an expansion card to couple the bus of the printed circuit card with a bus of the expansion card.

In yet another aspect of the present invention, a computer system is presented including a motherboard having a first bus extending to a first connector and a riser card having a second bus extending to a plurality of connectors and extending to a second connector adapted to mate with the first contact set of the motherboard to couple the first bus with the second bus. The computer system further includes a first expansion card having a third bus extending to a third connector adapted to mate with one of the plurality of connectors of the riser card to couple the third bus with the second bus, and an enclosure capable of housing the motherboard, the riser card, and the first expansion card.

In another aspect of the present invention, a method is presented including driving a first signal onto a motherboard bus, transmitting the first signal over the motherboard bus to a riser card bus, and transmitting the first signal over the riser card bus to a plurality of expansion card buses. In a further aspect, the method includes driving a second signal onto one of the expansion card buses, transmitting the second signal over the one of the expansion card buses to the riser card bus, and transmitting the second signal over the riser card bus to the motherboard bus.

### BRIEF DESCRIPTION OF THE DRAWINGS

The invention may be understood by reference to the following description taken in conjunction with the accompanying drawings, in which the leftmost significant digit(s) in the reference numerals denote(s) the first figure in which the respective reference numerals appear, and in which:

FIG. 1 is a stylized diagram of a conventional computer assembly;

FIG. 2 is a stylized diagram of a conventional computer assembly;

FIG. 3 is a partially-exploded front perspective view of a first embodiment of a computer system according to the present invention;

FIG. 4 is a stylized diagram of a computer assembly of the computer system shown in FIG. 3;

FIG. 5 is a block diagram of select interconnections between a motherboard, a riser board, and cards of the computer assembly shown in FIG. 4;

FIG. 6 is a partially-exploded rear perspective view of a second embodiment of a computer system according to the present invention;

FIG. 7 is a stylized diagram of a computer assembly of the computer system shown in FIG. 6; and

FIG. 8 is a block diagram of select interconnections between a motherboard, a riser board, and cards of the computer assembly shown in FIG. 7.

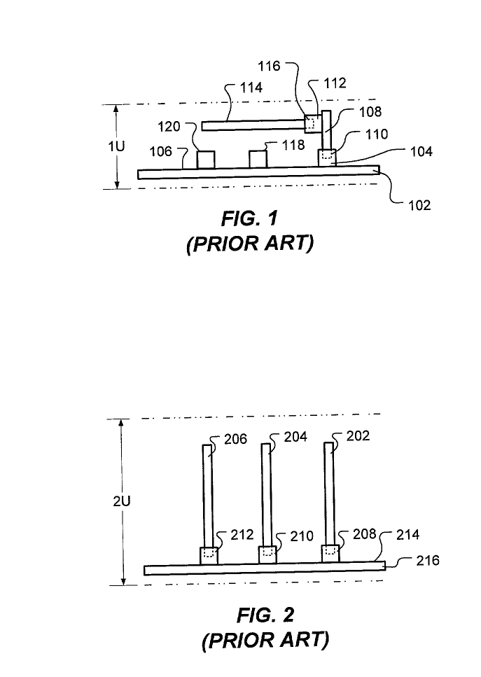

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF SPECIFIC EMBODIMENTS

Illustrative embodiments of the invention are described below. In the interest of clarity, not all features of an actual implementation are described in this specification. It will of course be appreciated that in the development of any such actual embodiment, numerous implementation-specific decisions must be made to achieve the developer's specific goals, such as compliance with system-related and business-related constraints, which will vary from one implementation to another. Moreover, it will be appreciated that such a development effort might be complex and time-consuming but would nevertheless be a routine undertaking for those of ordinary skill in the art having the benefit of this disclosure.

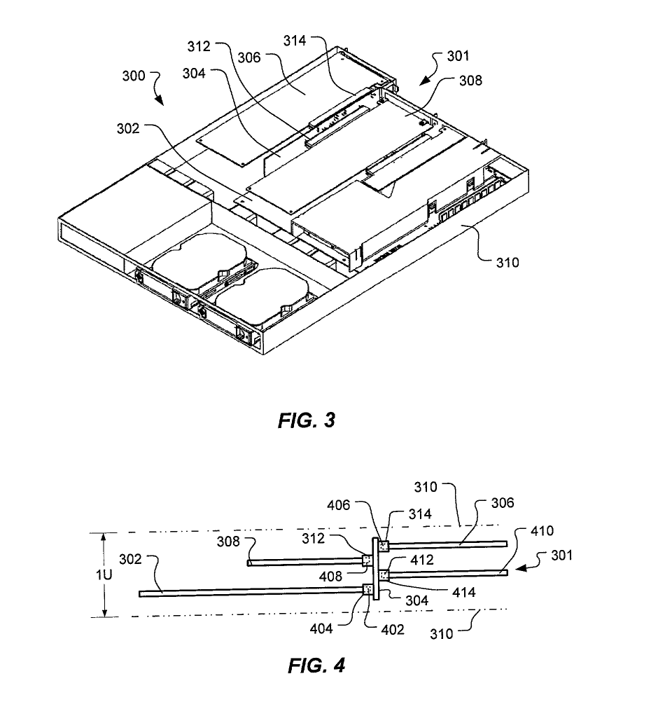

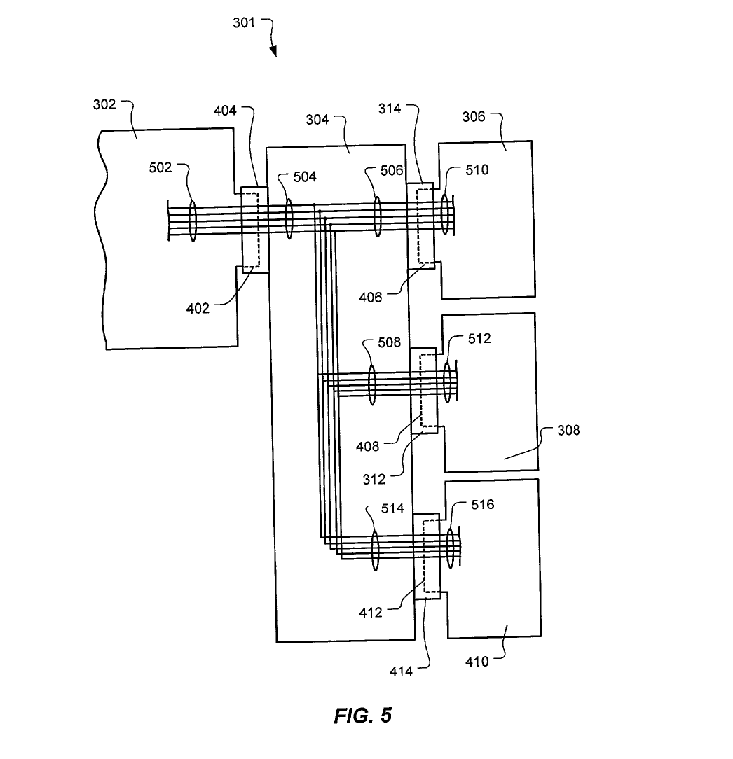

Referring to FIGS. 3-5, a first embodiment of a computer system 300 according to the present invention includes an enclosure 310 and a computer assembly including a motherboard 302, a riser card 304, and at least one of a plurality of expansion cards 306, 308, 410. A bus 502 of the motherboard 302 extends to a connector 402. A bus 504 of the riser card 304 extends to a connector 404 and includes a first branch 506 of the bus 504 extending to a connector 314, a second branch 508 of the bus 504 extending to a connector 312, and a third branch 514 of the bus 504 extending to a connector 414. The connector 314 is adapted to mate with a connector 406 of the expansion card 306. The expansion card 306 has a bus 510 extending to the connector 406 of the expansion card 306. The connector 312 is adapted to mate with a connector 408 of the expansion card 308. The expansion card 308 has a bus 512 extending to the connector 408 of the expansion card 308. The connector 414 is adapted to mate with a connector 412 of the expansion card 410. The expansion card 410 has a bus 516 extending to the connector 412 of the expansion card 410.

In the illustrated embodiment, however, either connector 312, 314, 414 of the riser card 304 is adapted to mate with either the connector 406 of the expansion card 306, the connector 408 of the expansion card 308, or the connector 412 of the expansion card 410. When mated as illustrated in FIGS. 3-5, electrical signals can travel in either direction between the bus 502 of the motherboard 302 and the buses 510, 512, 516 of the expansion cards 306, 308, 410 respectively, via the bus 504 of the riser card 304.

In the embodiment illustrated in FIGS. 3-5, the connector 402 of the motherboard 302 comprises a plurality of connector fingers adapted to mate with the connector 404 of the riser card 304. The connector 404 of the riser card 304 comprises a card edge connector. Each of the plurality of connectors 312, 314, 414 of the riser card 304 also comprises card edge connectors that are adapted to mate with either of the connectors 406, 408, 412 of the expansion cards 306, 308, 410. Accordingly, each of the connectors 406, 408, 412 comprises a plurality of connector fingers. Further, providing a connection with the riser card 304 along an edge of the motherboard 302 provides additional surface area of the motherboard for other devices, since no surface-mounted connector is required to connect the motherboard 302 with the riser card 304. Thus, as compared to conventional computer systems having enclosures with short heights (e.g., 1U rack mount enclosures), the present computer assembly 301 allows a plurality of expansion cards 306, 308, 410 to be interconnected with the motherboard 302 while being housed in a short height enclosure (e.g., 1U rack mount enclosure).

While the present invention is illustrated in FIGS. 3-5 as having three expansion cards 306, 308, 414, the present invention encompasses any number of expansion cards that can be physically located within a computer system enclosure, e.g., enclosure 310. Accordingly, it is within the scope of the present invention for the riser card 304 to have a number of branches (e.g., the branches 506, 508, 514) and a number of connectors (i.e., the connectors 312, 314, 414) commensurate with the possible number of expansion cards in the computer assembly 301.

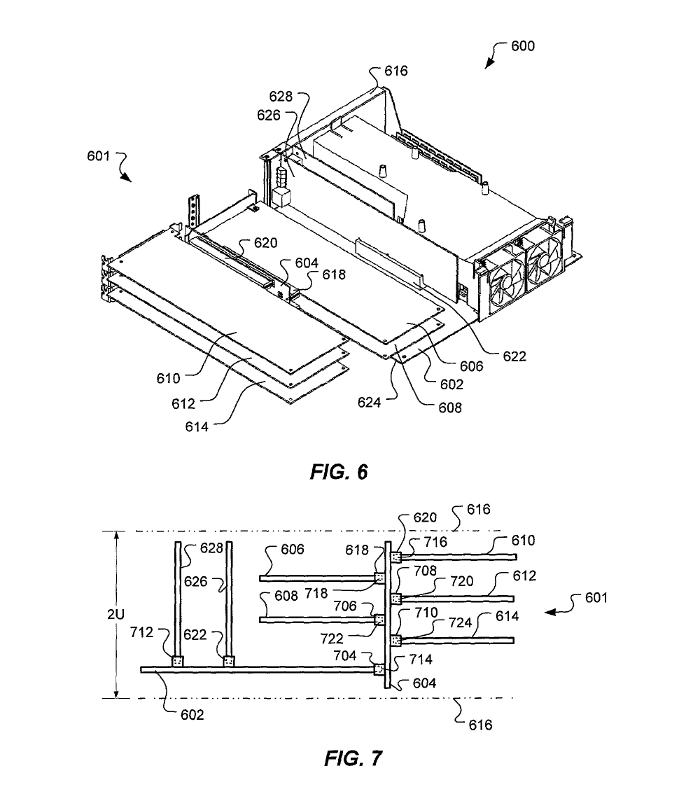

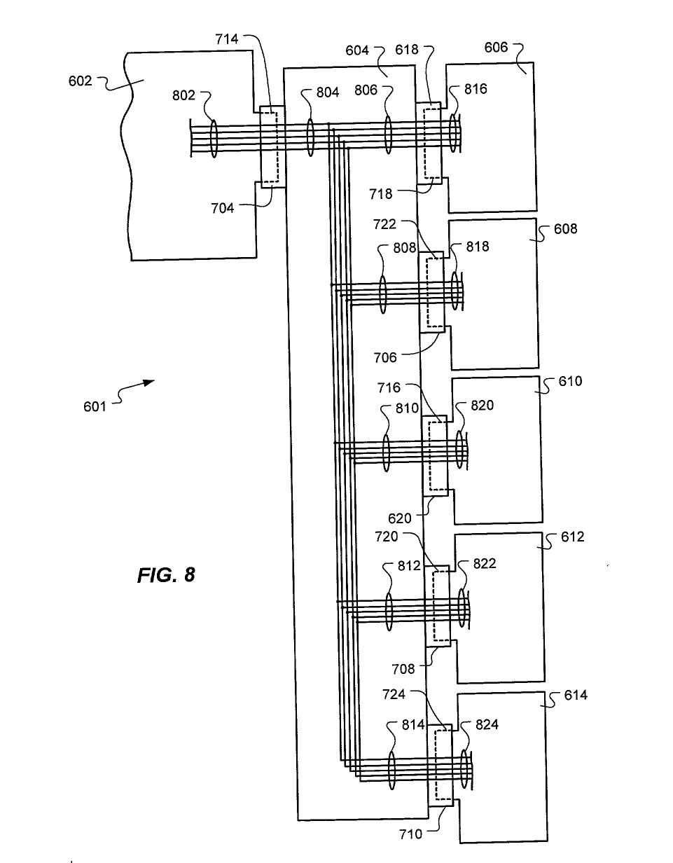

For example, FIGS. 6-8 illustrate a second embodiment of a computer system 600 according to the present invention includes a computer assembly 601 having a motherboard 602, a riser card 604, and a plurality of expansion cards 606, 608, 610, 612, 614 disposed within an enclosure 616. A bus 802 of the motherboard 602 extends to a connector 714. A bus 804 of the riser card 604 extends to a connector 704 and includes a plurality of branches 806, 808, 810, 812, 814 extending to connectors 618, 706, 620, 708, 710. The connectors 718, 722, 716, 720, 724 of the expansion cards 606, 608, 610, 612, 614, respectively, are adapted to mate with any of the connectors 618, 706, 620, 708, 710 of the riser card 604. Each of the expansion cards 606, 608, 610, 612, 614 has a bus (i.e., the buses 816, 818, 820, 822, 824) extending to one the connectors 718, 722, 716, 720, 724, as shown in FIG. 8. When connected as illustrated, electrical signals can travel in either direction between the bus 802 of the motherboard 602 and the buses 816, 818, 820, 822, 824 of the expansion cards 606, 608, 610, 612, 614, respectively, via the riser card 604 by traveling along the bus 804, including the branches 806, 808, 810, 812, 814.

The motherboard 602 further includes surface connectors 622, 712 that are spaced away from an edge 624 of the motherboard 602 so that expansion cards 626, 628 may be interconnected with the motherboard 602 via the surface connectors 622, 712, respectively, without obstructing the expansion cards 606, 608. While two surface connectors (e.g., the surface connectors 622, 712) are illustrated, the present invention encompasses any number of surface connectors of the motherboard 602.

In the embodiment illustrated in FIGS. 6-8, the connector 714 of the motherboard 602 comprises a plurality of connector fingers adapted to mate with the connector 704 of the riser card 604. The connector 704 of the riser card 604 comprises a card edge connector. Each of the plurality of connectors 620, 618, 708, 706, and 710 of the riser card 604 comprises a card edge connector that is adapted to mate with any of the connectors 718, 722, 716, 720, 724 of the expansion cards 606, 608, 610, 612, 614. Further, providing a connection with the riser card 604 along an edge of the motherboard 602 provides additional surface area of the motherboard for other devices, since no surface-mounted connector is required to connect the motherboard 602 with the riser card 604. Thus, as compared to conventional computer systems having motherboards with only surface connectors, the present computer assembly 601 allows a greater number of expansion cards 606, 608, 610, 612, 614 to be interconnected with the motherboard 602 while being housed in an enclosure (e.g., a 2U rack mount enclosure).

The particular embodiments disclosed above are illustrative only, as the invention may be modified and practiced in different but equivalent manners apparent to those skilled in the art having the benefit of the teachings herein. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed is:

1. A computer assembly, comprising:
a motherboard having a first bus extending to a first connector;
a riser card having a second bus extending to a plurality of connectors and extending to a second connector adapted to mate with the first connector of the motherboard to couple the first bus with the second bus; and
a first expansion card having a third bus extending to a third connector adapted to mate with one of the plurality of connectors of the riser card to couple the third bus with the second bus.

2. A computer assembly, according to claim 1, wherein:
the first connector comprises a plurality of connector fingers;
the second connector comprises a card edge connector;
the third connector comprises a plurality of connector fingers; and
the plurality of connectors of the riser card are card edge connectors.

3. A computer assembly, according to claim 1, wherein each of the first bus, the second bus, and the third bus comprises a bus selected from the group consisting of a peripheral component interface bus, an industry standard architecture bus, and a proprietary bus.

4. A computer assembly, according to claim 1, wherein the expansion card is generally parallel to the motherboard when the first connector is mated with the second connector and the third connector is mated with one of the plurality of connectors.

5. A computer assembly, according to claim 1, wherein the plurality of connectors comprises three connectors.

6. A computer assembly, according to claim 5, wherein the computer assembly is adapted to fit within a 1U enclosure.

7. A computer assembly, according to claim 1, wherein the plurality of connectors comprises five connectors.

8. A computer assembly, according to claim 7, wherein the computer assembly is adapted to fit within a 2U enclosure.

9. A computer assembly, according to claim 1, wherein the motherboard further comprises a sixth connector mounted to a surface of the motherboard and adapted to mate with a second expansion card, and wherein the first expansion card does not obstruct a mating of the motherboard and the second expansion card when the fifth connector is mated with any one of the plurality of connectors.

10. A computer assembly, according to claim 1, wherein the computer assembly is adapted to fit within a 1U enclosure.

11. A computer assembly, according to claim 1, wherein the computer assembly is adapted to fit within a 2U enclosure.

12. A riser card comprising:
a primary connector;
a plurality of secondary connectors; and
a printed circuit card having a bus extending to the primary connector and to the plurality of secondary connectors,
wherein the primary connector is adapted to mate with a connector of a motherboard to couple the bus of the printed circuit card with a bus of a motherboard, and
wherein each of the plurality of secondary connectors is adapted to mate with a connector of an expansion card to couple the bus of the printed circuit card with a bus of the expansion card.

13. A riser card, according to claim 12, wherein the primary connector and the plurality of secondary connectors are card edge connectors.

14. A riser card, according to claim 12, wherein the bus of the printed circuit board comprises a bus selected from the group consisting of a peripheral component interface bus, an industry standard architecture bus, and a proprietary bus.

15. A riser card, according to claim 12, wherein the primary connector and the plurality of secondary connectors are card edge connectors.

16. A riser card, according to claim 12, wherein the plurality of secondary connectors comprises two secondary connectors.

17. A riser card, according to claim 16, wherein the riser card is adapted to fit within a 1U enclosure.

18. A riser card, according to claim 12, wherein the plurality of secondary connectors comprises five secondary connectors.

19. A riser card, according to claim 18, wherein the riser card is adapted to fit within a 2U enclosure.

20. A riser card, according to claim 12, wherein the riser card is adapted to fit within a 1U enclosure.

21. A riser card, according to claim 12, wherein the riser card is adapted to fit within a 2U enclosure.

22. A computer system, comprising:
a motherboard having a first bus extending to a first connector;
a riser card having a second bus extending to a plurality of connectors and extending to a second connector adapted to mate with the first contact set of the motherboard to couple the first bus with the second bus;
a first expansion card having a third bus extending to a third connector adapted to mate with one of the plurality of connectors of the riser card to couple the third bus with the second bus; and
an enclosure capable of housing the motherboard, the riser card, and the first expansion card.

23. A computer system, according to claim 22, wherein:
the first connector comprises a plurality of connector fingers;
the second connector comprises a card edge connector;
the third connector comprises a plurality of connector fingers; and
the plurality of connectors of the riser card are card edge connectors.

24. A computer system, according to claim 22, wherein each of the first bus, the second bus, and the third bus comprises a bus selected from the group consisting of a peripheral component interface bus, an industry standard architecture bus, and a proprietary bus.

25. A computer system, according to claim 22, wherein the expansion card is generally parallel to the motherboard when the first connector is mated with the second connector and the third connector is mated with one of the plurality of connectors.

26. A computer system, according to claim 22, wherein the plurality of connectors comprises three connectors.

27. A computer system, according to claim 26, wherein the riser card is adapted to fit within a 1U enclosure.

28. A computer system, according to claim 22, wherein the plurality of connectors comprises five connectors.

29. A computer system, according to claim 28, wherein the riser card is adapted to fit within a 2U enclosure.

30. A computer system, according to claim 22, wherein the motherboard further comprises a sixth connector mounted to a surface of the motherboard and adapted to mate with a second expansion card, and wherein the first expansion card does not obstruct a mating of the motherboard and the second expansion card when the fifth connector is mated with any one of the plurality of connectors.

31. A computer system, according to claim 22, wherein the riser card is adapted to fit within a 1U enclosure.

32. A computer system, according to claim 22, wherein the riser card is adapted to fit within a 2U enclosure.

33. A method, comprising:
driving a first signal onto a motherboard bus;
transmitting the first signal over the motherboard bus to a riser card bus; and
transmitting the first signal over the riser card bus to at least one of a plurality of expansion card buses.

34. A method, according to claim 33, further comprising:
driving a second signal onto one of the expansion card buses;
transmitting the second signal over the at least one of the plurality of expansion card buses to the riser card bus; and
transmitting the second signal over the riser card bus to the motherboard bus.

35. An apparatus, comprising:
means for driving a first signal onto a motherboard bus;
means for transmitting the first signal over the motherboard bus to a riser card bus; and
means for transmitting the first signal over the riser card bus to at least one of a plurality of expansion card buses.

36. An apparatus, according to claim 35, comprising:
means for driving a second signal onto one of the expansion card buses;
means for transmitting the second signal over the at least one of the plurality of expansion card buses to the riser card bus; and
means for transmitting the second signal over the riser card bus to the motherboard bus.
